(19) United States
(12) Patent Application Publication
(10) Pub. No.: US 2025/0146159 A1
(43) Pub. Date: May 8, 2025

(54) METHOD OF PROCESSING ARTICLES AND CORRESPONDING APPARATUS

(71) Applicant: STMicroelectronics International N.V., Geneva (CH)

(72) Inventor: Paolo CREMA, Vimercate (IT)

(73) Assignee: STMicroelectronics International N.V., Geneva (CH)

(21) Appl. No.: 18/933,194

(22) Filed: Oct. 31, 2024

(30) Foreign Application Priority Data
Nov. 2, 2023 (IT) 102023000023049

(51) Int. Cl. C25D 5/48; C25D 3/38; C25D 3/46; C25D 5/10; C25D 7/12; C25D 17/00

(52) U.S. Cl. CPC C25D 5/48; C25D 3/38; C25D 3/46; C25D 5/10; C25D 17/001; C25D 7/12

(57) ABSTRACT

Articles carried by a carrier are processed in a sequence of processing steps that includes a plating step where a base layer of plating material is plated on a surface of the carrier. The plating material plated on the surface of the carrier is selectively stripped to partially remove the plating material to reduce e thickness of the base layer of plating material plated present on the surface of the carrier. A residual protective layer of plating material having the reduced thickness is left on the surface of the carrier.

### PRIORITY CLAIM

This application claims the priority benefit of Italian Application for Patent No. 102023000023049 filed on Nov. 2, 2023, the content of which is hereby incorporated by reference in its entirety to the maximum extent allowable by law.

### TECHNICAL FIELD

The description relates to processing articles via processing baths.

Solutions as described herein can be advantageously applied in plating equipment used in manufacturing semiconductor devices, for instance.

### BACKGROUND

Current manufacturing processes of semiconductor devices involve processing articles such as substrates (leadframes, for instance) in a sequence of processing baths such as (electro) plating baths.

For this purpose, leadframes are mounted on a stainless steel carrier and conveyed through the sequence of electroplating baths.

The carrier is (at least partially) dipped in the electroplating baths causing plating material (copper, silver and/or tin, for instance) to accumulate thereon.

In order to counter contamination of processing baths and/or undesired material accumulation on the carrier, the carrier passes through stripping baths, that is, baths comprising chemical agents capable of removing the plating material plated on the surface of the carrier.

Despite these stripping agents being specifically developed, a small amount of stainless steel is still etched, thus causing wear and thinning of the carrier that needs to be replaced regularly.

For example, in Non-Etching Adhesion Promoter (NEAP) processes (where processing of leadframes comprises a copper and silver electroplating bath and corresponding silver and copper stripping) the stainless-steel carrier may need to be replaced every month.

Reference is made to United States Patent Application Publication Nos. 2010/0187084 and 2003/0230491, Chinese Patent Application No. 104293222, and PCT Published Application WO 2000052231 as providing background information in the related technological area.

There is a need in the art to contribute in adequately dealing with such an issue.

### SUMMARY

One or more embodiments relate to a method.

One or more embodiments relate to a corresponding apparatus.

Solutions as described herein aim at extending the life time of a carrier for use in plating processes of articles such as leadframes.

Solutions as described herein may advantageously be applied when one (or more) layer(s) of plating material is formed on the surface of the carrier in response to exposure of the carrier to a processing bath.

In solutions as described herein, a residual layer of plating material grown/deposited on a surface of a carrier is left on the surface of the carrier.

In solutions as described herein, a residual, protective layer of plating material protects the carrier from the wearing action of the stripping baths.

### BRIEF DESCRIPTION OF THE DRAWINGS

One or more embodiments will now be described, by way of example only, with reference to the annexed figures, wherein:

FIG. 1 is a flow chart illustrative of the processing steps involved in an exemplary manufacturing process of semiconductor devices,

FIGS. 2A to 2C is a sequence of cross-sectional views of a carrier as considered herein, illustrative of a sequence of steps according to embodiments of the present description,

FIGS. 3 to 6 are flow charts (FIGS. 3 and 5) and diagrams (FIGS. 4 and 6) illustrative of possible embodiments of the present description,

FIGS. 7A to 7D and FIG. 8 are a sequence of cross-sectional views and a flow chart, illustrative of embodiments of the present description where more than one layer of plating material is deposited on the carrier, and

FIG. 9 is illustrative of an apparatus for processing articles according to embodiments of the present description.

### DETAILED DESCRIPTION

The figures are drawn to clearly illustrate the relevant aspects of the embodiments and are not necessarily drawn to scale.

The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

Current manufacturing processes of semiconductor devices may involve processing articles by dipping them in one or more plating baths.

In examples considered herein, the articles are leadframes used in manufacturing semiconductor devices.

Various types of semiconductor devices comprise integrated circuit (IC) semiconductor chip/chips or die/dice (these terms are used herein as synonymous) mounted on a sculptured metallic substrate, referred to as leadframe.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

In certain cases, a leadframe can be of the pre-molded type, that is a type of leadframe comprising a sculptured metal (copper, for instance) structure formed by etching a metal sheet and comprising empty spaces that are filled by a resin “pre-molded” on the sculptured metal structure.

Current manufacturing processes of leadframes for (integrated circuit) semiconductor devices may involve growing material on the surface of the leadframes via a sequence of processing baths such as electrolytic plating baths, for instance.

For that purpose, a plurality of leadframes is arranged in a leadframe reel (or panel) and concurrently processed by attaching the reel to a carrier such as a conveyor belt configured to move the leadframes through treatment vats filled with the processing baths.

As mentioned, in the examples described herein, reference will be made to processing of substrates (such as leadframes) for IC semiconductor devices; however, this is merely exemplary of an advantageous application of solutions as described herein in so far as embodiments of the present description may advantageously be applied in processing articles other than leadframes.

As mentioned, processing of leadframes may involve a plurality of electrolytic plating steps. In electrolytic plating, an electric field is established in the bath between anodes and the leadframe strip (attached to the carrier), acting as a cathode. In that way positively charged metal ions in the liquid bath are forced to move to the cathode where they give up their charge and deposit as metal on the surface of the leadframe strip.

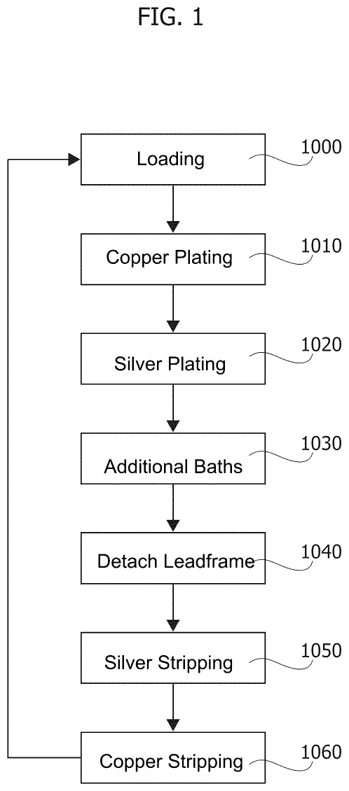

FIG. 1 is a flow chart illustrative of a possible sequence of processing steps involved in non-etching adhesion promoter (NEAP) processing of leadframes.

NEAP processing of leadframes involves loading 1000 the leadframes candidate for processing on a carrier. As mentioned in the foregoing the carrier may be a stainless-steel carrier such as a reel-to-reel belt configured to have attached thereto (via clips, for instance) a reel or a panel comprising a plurality of leadframes.

The carrier having the leadframes attached thereto is dipped in a first processing bath 1010. The first processing bath 1010 may be an electroplating bath for plating/growing a first material on the leadframes carried by the carrier.

In the exemplary case of NEAP processing the first plating bath 1010 may be a copper plating bath. A layer of copper is grown on the leadframe under processing and, due to the fact that the carrier is (at least partially) dipped in the copper plating bath, a layer of the first material (copper, for instance) is grown/deposited on the surface of the stainless steel carrier.

Subsequently to a first plating bath 1010 (copper plating bath, in the case of NEAP processing) leadframes are processed in a second plating bath 1020 for growing/depositing a second material. NEAP process, for instance, may involve a silver plating bath 1020 subsequently to the copper plating bath 1010.

To that effect, the carrier having the leadframes attached thereto is dipped in a second processing bath 1020 causing the second material (silver, for instance, in the case of NEAP processes) to grow/deposit on the layer of first material (copper, for instance) grown on the surface of the carrier.

Leadframes are subsequently subjected to a sequence of processing steps (comprehensively referred to with the reference 1030 in the flow diagram of FIG. 1), possibly comprising additional processing baths that may depend on the particular semiconductor device/substrate under processing.

For instance, further processing steps 1030 may comprise an anti-epoxy-bleed-out (anti-EBO) step and/or a drying step.

Processed leadframes are thus detached 1040 (“off-loading”) from the carrier.

It is noted that the sequence of step as described in the foregoing is a brief overview of a sequence of the processing steps involved in NEAP processing of leadframes; as known to those skilled in the art, NEAP processes may comprise further processing steps/baths such as “activating” baths preceding the plating baths (copper 1010 and silver 1020 plating baths, for instance). A NEAP process as described in the foregoing is conventional in the art which makes it unnecessary to provide a more detailed discussion herein.

Exposure to a sequence of (electro) plating baths causes layers of (possibly different) materials to grow/deposit on the surface of the carrier. In order to counter undesired accumulation of material on the surface of the carrier, material grown/deposited the carrier is removed by exposing (dipping) the carrier to a sequence of stripping baths.

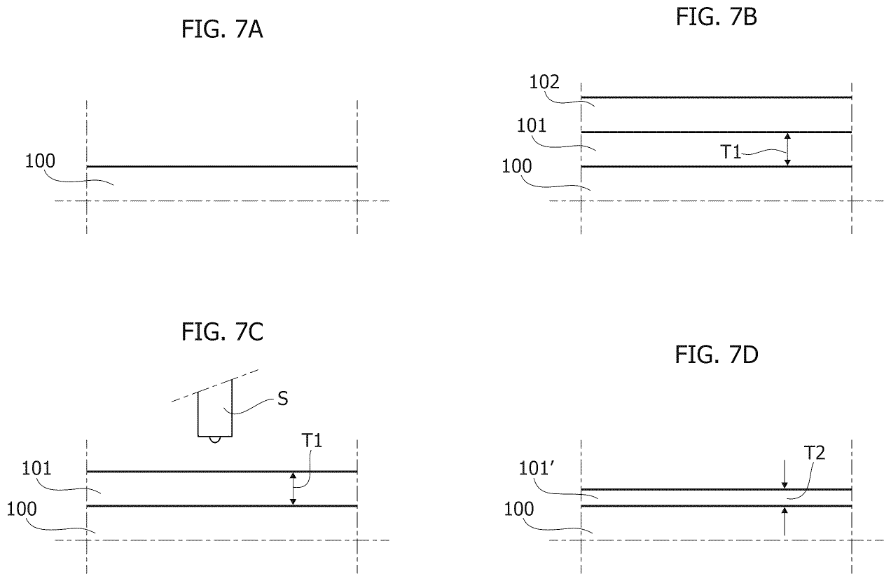

In the exemplary case of a carrier used for NEAP processing of leadframes, the surface of the carrier is (at least partially) plated with a layer of copper (on the stainless steel surface of the carrier) and a layer of silver (plated on the layer of copper). A schematic cross-sectional view of the carrier with two different layers plated thereon is illustrated in FIG. 7B (discussed in the following) where the (stainless steel) carrier is referenced with the reference 100 and the first (copper, for instance) and second (silver, for instance) layers are referenced with the references 101 and 102, respectively.

Referring again to FIG. 1, subsequently to detaching the leadframes from the carrier, the carrier is dipped in a silver stripping bath 1050 and, subsequently, to a copper stripping bath 1060 to remove the silver and the copper layers grown on the carrier.

The carrier may thus be used again to process another leadframe reel or panel (another batch of articles, in general) in the sequence of processing baths described in the foregoing. This fact is illustrated in the flow diagram of FIG. 1 where the block 1060 (a copper stripping bath in the NEAP process) is connected to the block 1000 indicating the loading of (another) leadframe reel on the carrier.

Stripping baths 1050, 1060 comprise chemical agents that are specifically developed to remove the (silver and copper) layers plated on the surface of the carrier facilitated by a stripper current.

Despite these stripping agents being specifically developed, a relatively small amount of stainless steel is still etched away in the process; a repeated exposure of the carrier to such stripping baths may cause undesired wear and thinning of the carrier that may need to be replaced regularly.

In the exemplary case of NEAP process described previously, the carrier may need to be replaced about every month.

Solutions as described herein aim at extending the lifetime of a carrier for use in manufacturing processes of articles involving plating baths.

Solutions as described herein may advantageously be applied when one (or more) layer(s) of plating material is formed on the surface of the carrier in response to exposure of the carrier to a processing bath.

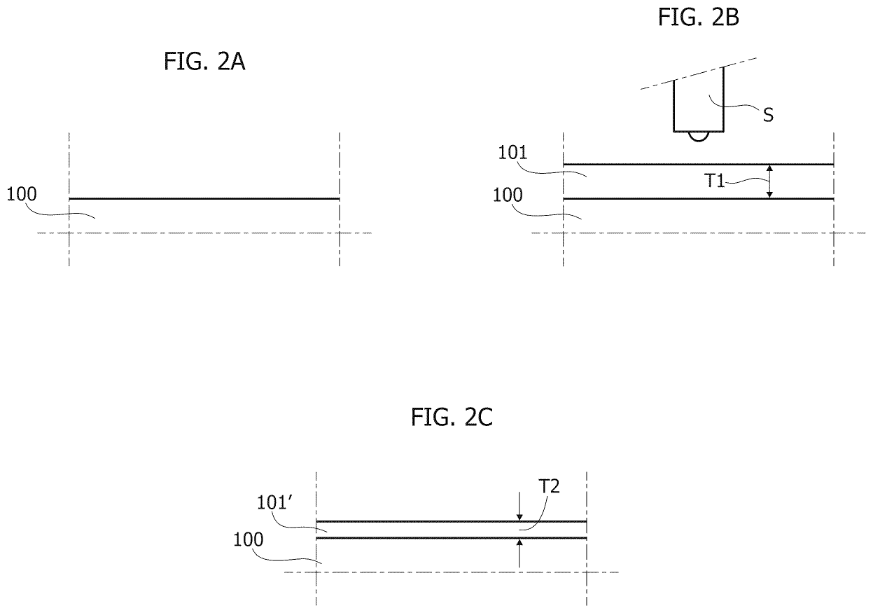

In solutions as described herein, a residual, protective layer of plating material is left of the surface of the carrier to protect the carrier from the wearing action of the stripping baths. FIGS. 2A to 2C are illustrative of processing steps according to embodiments of the present description.

It is noted that the sequence of steps illustrated in FIGS. 2A to 2C (and FIGS. 7A to 7D, discussed later) are illustrative of the processing steps (plating baths and stripping baths) of interest herein; other processing steps are not visible for simplicity.

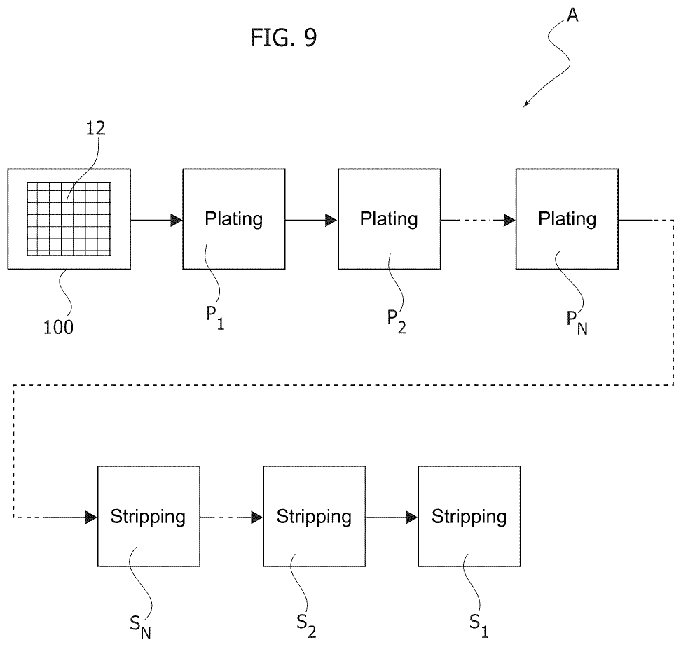

FIG. 2A is a cross-sectional view illustrative of a surface of (a stainless steel) carrier 100 configured to have articles (such as leadframes) attached thereto to facilitate processing of the articles by dipping them in processing baths (this is illustrated in FIG. 9 that illustrates articles-referenced with the reference 12—attached to a carrier 100).

The carrier 100 (carrying the articles 12 to be processed) is dipped in a processing bath (a plating bath, for instance) that causes plating material to grow/deposit on the surface of the carrier 100.

FIG. 2B is illustrative of a layer 101 of plating material (copper or tin, for instance) grown on the surface of the carrier 100 in response to the carrier being exposed to a plating bath. The layer 101 has a first thickness T1 that depends on the composition and parameters of the plating bath.

As discussed previously in the exemplary case of NEAP processing, the layer 101 may be a layer of copper grown via exposure to a copper (electro) plating bath and the thickness T1 of the layer 101 deposited on the carrier 100 may depend on the thickness of the copper layer that is desired to grow on the leadframes 12 (attached to the carrier 100) under processing.

The carrier 100 is subsequently dipped (possibly after unloading the processed articles) in a stripping bath in order to counter undesired accumulation of material 101 on the carrier 100.

FIG. 2C is illustrative of the layer 101 of plating material that is partially removed from the surface of the carrier 100.

The stripping bath may be configured, by choosing an adequate exposure time, for instance, to leave a residual layer 101′ having a desired thickness T2.

As illustrated, a residual layer 101′ of plating material (copper, for instance) having a thickness T2, possibly less than the thickness T1 (T2<T1), is left on the surface of the carrier 100.

Leaving such a residual layer 101′ on the surface of the carrier reduces wearing of the carrier 100 due to exposure to a stripping bath. That is, the residual layer 101′ acts as a protective layer for the carrier 100, countering exposure of the (stainless steel) carrier 100 to the stripping bath and the undesired etching of the material of the carrier 100.

A residual layer 101′ having a thickness T2 between 5 and 10 microns has been found to provide adequate protection against the wearing action of the stripping bath.

According to embodiments of the present description, the amount of plating material that is removed from the surface of the carrier 100 may be determined by measuring the thickness T of the layer 101 of plating material (copper, for instance).

Referring back to FIG. 2B, one or more optical sensors S may be used to measure the thickness T1 of the layer 101 deposited on the surface of the carrier 100 in response to exposure to a plating bath.

The amount of plating material removed in the stripping step may be selected as a function of the measured thickness T1 of the layer 101 plated on the surface of the carrier 100. The parameters of the stripping bath may be elected to remove a determined amount of material from the layer 101 to leave a residual, protective layer 101′ having a desired thickness T2, preferably between 5 and 10 microns.

Advantageously, the stripping step is skipped if the layer 101 of plating material has a thickness T1 (measured via optical sensors S, for instance) that is in a desired thickness range (5 to 10 microns, for instance). For instance, the stripping may be skipped by turning OFF the stripper current in the stripping bath, thus deactivating the stripping bath.

Said in other words, a layer 101 of plating material plated on a surface of the carrier 100 in response to exposure to a plating step is selectively stripped (stripper current ON/OFF) to partially remove the layer 101 of plating material plated on the surface of the carrier 100 leaving a residual protective layer 101′ of plating material on the surface of the carrier 100.

Solutions as described in the foregoing lend itself to be implemented in manufacturing processes where a (same) carrier 100 is used for a plurality of processing cycles, wherein a different batch of articles 12 is processed in every processing cycle, for instance.

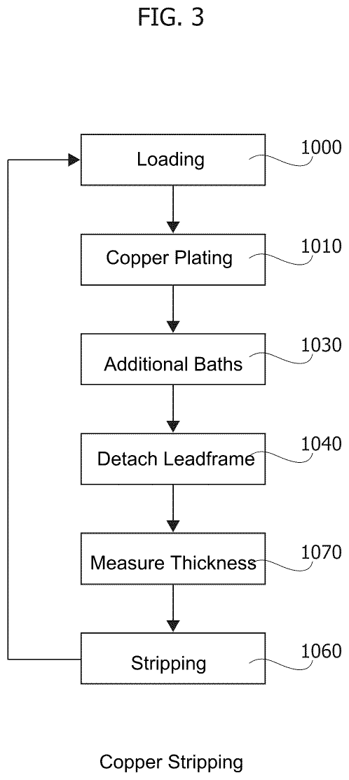

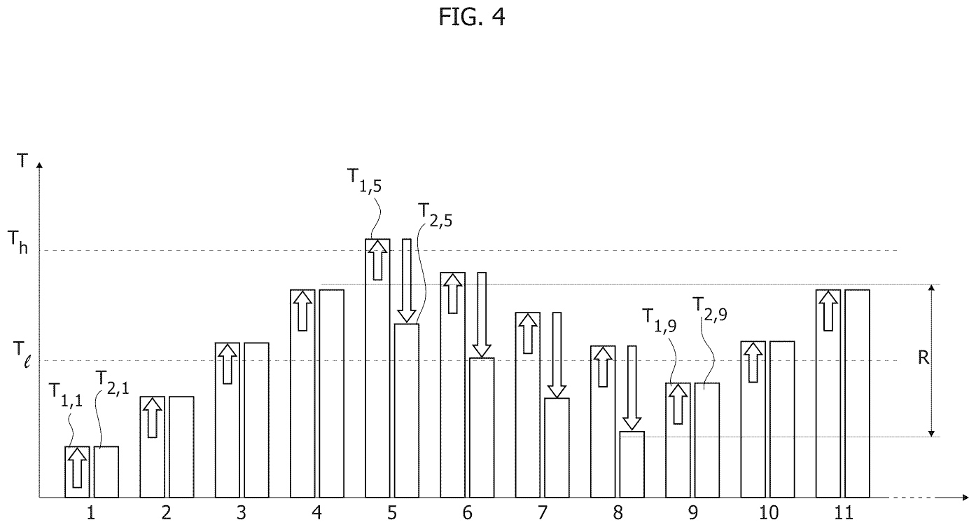

FIGS. 3 and 4 are a flow chart and a diagram, respectively, illustrative of embodiments of the present description where a same carrier 100 is used in a plurality of processing cycles.

Similarly to what has been discussed in relation to FIG. 1, the steps referenced in FIG. 3 with the references 1000, 1010, 1030 and 1040 comprise: loading 1000 the articles 12 candidate for processing on a carrier 100; exposing the articles 12 to a plating bath 1010, resulting in a layer 101 being deposited on the surface of the carrier 100; further processing 1030 of the articles 12 carried by the carrier 100, and unloading 1040 the (processed) articles 12.

The sequence illustrated in FIG. 3 is merely exemplary of a sequence of processing steps of articles 12 that comprises one plating step 1010; for example, other processing steps (other than a plating step) may be performed prior to the plating step 1010.

Whatever the particular processing steps 1030, after processing of articles 12 a layer 101 of plating material (copper, for instance) is deposited on a surface of the carrier 100 in response to the plating step 1010.

The thickness T1 of the layer 101 deposited on the surface of the carrier may be measured 1070 via optical sensors S, for instance, and the measured thickness T1 of the layer 101 may be used to configure the subsequent stripping bath 1060.

That is, the amount of material that is removed from the layer 101 via a stripping 1060 bath may be selected as a function of the thickness T1 of the layer 101 (prior to the stripping bath) and on the thickness T2 of the residual layer 101′ that it is desired to leave on the surface of the carrier 100.

As illustrated in FIG. 3, subsequently to the stripping bath 1060, the (same) carrier 100 is loaded 1000 with another batch of articles 12 candidate for processing.

FIG. 4 is a diagram illustrative of the evolution of the thickness (on the y axis) of the layer of plating material as a function of the number of processing cycles the carrier has gone through (on the x axis).

For each processing cycle two thickness values are illustrated in the diagram of FIG. 4, namely: the thickness of the layer 101 of plating material prior to selective stripping 1060 at the processing cycle labelled “i”, referenced with the references T_{1,i}; and the thickness of the layer 101′ of plating material subsequently to selective exposure to a stripping bath 1060 at the processing cycle labelled “i”, referenced with the references T_{2,i}.

For simplicity, these values are illustrated in FIG. 4 only for the first, the fifth and the ninth cycle.

Two threshold values, an upper threshold Th and a lower threshold T₁, are also illustrated in the diagram of FIG. 4.

In the embodiments described in relation to FIGS. 3 and 4, the thickness T_{1,i} of the layer 101 prior to the i^{th} stripping bath is measured (via optical sensors S, for instance) and used to determine, by comparison with the threshold values Tₕ and Tₗ, whether turning ON/OFF the stripper current of the subsequent stripping bath 1060.

As illustrated, the stripper current in the stripping bath 1060 of the first four processing cycles is OFF and no material is removed in the stripping bath 1060; consequently, the thickness of the layer of plating material before and after the stripping bath 1060 has the same values (T_{1,1}=T_{2,1}, for instance).

At every processing cycle, additional plating material is deposited on the residual layer 101′ left on the surface of the carrier 100 in the preceding working cycle; plating material accumulates (T_{1,1}<T_{1,2}<T_{1,3}<T_{1,4}) on the surface of the carrier 100 due to the repeated exposure of the carrier 100 to plating baths 1010.

After a certain number of processing cycles the measured thickness of the layer 101 before the stripping bath 1060 will be greater than the upper threshold Tₕ. In the example illustrated in FIG. 4 the thickness of the layer 101 is found to be greater than the upper threshold after the fifth processing cycle, that is T_{1,5}>Tₕ. Consequently, the stripper current in the following (fifth) stripper bath 1060 is turned ON and a certain amount of plating material is removed (etched away) from the surface of the carrier 100 in the stripping bath 1060.

Desirably, the amount of plating material removed in the stripping bath 1060 (with the stripper current turned ON) is larger than the amount of material that accumulates during a plating step 1010 (this fact is illustrated in FIG. 4, wherein T_{2,5}<T_{2,4}).

The stripper current of the stripper baths 1060 at following processing cycles may be kept ON as long as the thickness of the layer 101 of plating material as measured 1070 prior to the stripping bath 1060 is greater than a lower threshold T₁.

As illustrated, the thickness of the layer 101 (prior to each stripping bath 1060) decreases from cycle 5 to 9 and eventually, at the ninth cycle in the example of FIG. 4, the measured thickness is less than the lower threshold T_{1,9}<T₁.

Consequently, the stripper current of the ninth processing cycle is turned OFF, and no plating material is removed in the ninth stripping bath 1060 (T_{9,2}=T_{9,1}).

The stripper current may be kept OFF for the subsequent processing cycles—thus letting plating material to accumulate on the carrier 100 cycle after cycle—as long as the thickness of the layer 101 (as measured 1070 prior to the stripping bath 1060) is less than the high threshold Tₕ.

As illustrated, the thickness of the residual layer 101′ “oscillates” with the processing cycles staying—possibly with the exception of the first processing cycles—within the range of values referenced with the reference R in the figure.

It may be appreciated that, for a given amount of plating material that is deposited on the carrier 100 after each plating step 1010 (the amount depending on the articles 12 under processing, for instance), the thickness of the residual layer 101′ may be maintained within a desired range R by adjusting the threshold values Tₕ, Tₗ and/or the amount of plating material that is removed in the stripping bath 1060 (when the stripper current is ON).

As mentioned previously, a thickness of the residual layer 101′ in the range R between 5 and 10 microns has been found to give adequate protection to a stainless-steel carrier 100 of the type conventionally used in the manufacturing processes of semiconductor devices (such as in NEAP process, for instance).

It may be appreciated that solutions where the thickness of the layer of plating material is measured prior to a stripping bath 1060 may be implemented in other ways than what is exemplified in FIG. 4.

For instance, only one threshold Tₕ may be contemplated with the stripper current of the stripping bath 1060 kept OFF as long as the thickness (as measured 1070 prior to the stripping bath 1060) of the layer of plating material that accumulates on the carrier at every processing cycle is below the threshold. The stripper current may be turned ON when the measured thickness is above the threshold and a selected, partial amount of plating material is removed from the surface of the carrier 100 leaving a residual protective layer 101′ (having a thickness of 5 microns, for instance). The stripper current in the stripping bath 1060 of the following processing cycles may be kept OFF thus letting plating material to accumulate again on the carrier.

The flow chart of FIG. 3 and the diagram of FIG. 4 are thus exemplary of plating material 101 plated on said surface of the carrier 100 being selectively exposed to a stripping bath to remove plating material 101 plated on the surface of the carrier 100.

The wording “selectively” highlights the fact that: in processing cycles such as the cycles labelled 1 to 4 in FIG. 4 no stripping is contemplated, wherein plating material is not removed from the surface of the carrier 100; and, conversely, in processing cycles such as the cycles labelled 5 to 8 in FIG. 4 stripping is contemplated, wherein plating material is removed from the surface of the carrier 100.

In any case a residual protective layer 101′ of plating material is left on the surface of the carrier 100.

As discussed, the stripping bath is selectively activated as a function of the thickness T1 of the layer 101 of plating material plated on the surface of the carrier 100.

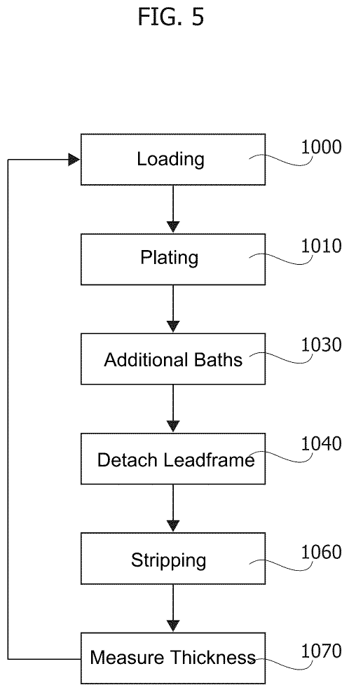

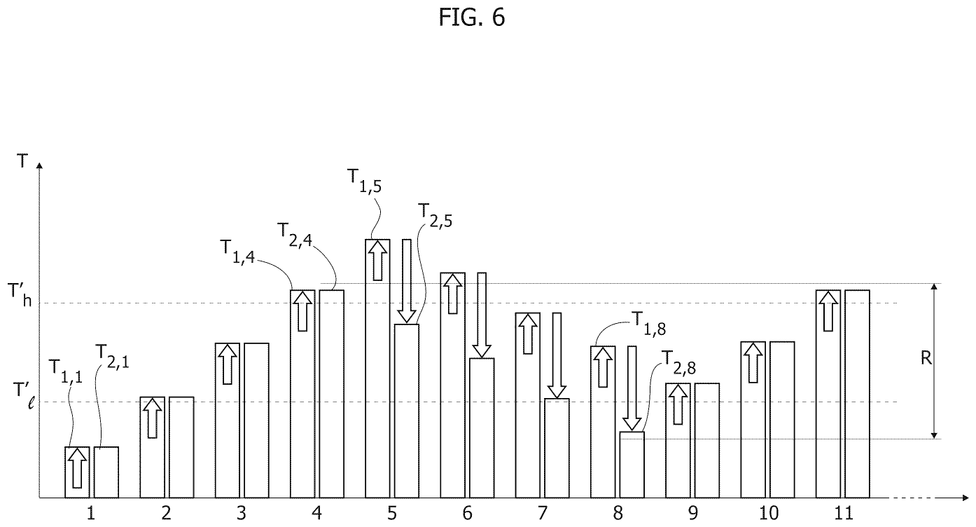

FIGS. 5 and 6 are a flow chart and a diagram, respectively, illustrative of further embodiments of the present description where a same carrier 100 is used in a plurality of processing cycles.

As illustrated in FIG. 5, articles 12 are processed in a similar way to what has been described in relation to FIG. 3; that is, articles 12 are loaded 1000 on a carrier 100, processed 1010, 1030 and unloaded 1040 from the carrier 100.

In the cases considered herein, processing of articles 12 (leadframe, for instance) comprises a plating step 1010 (an electroplating bath, for instance) and additional processing steps, indicated with the reference 1030, that may depend on the type of articles 12 candidate for processing.

Again, those skilled in the art may appreciate that this sequence is merely exemplary insofar as additional steps may be added; for example, further processing steps (not visible in FIG. 5 for simplicity) may be performed prior to the plating step 1010.

Whatever the particular processing steps 1030, after processing of articles 12, that is after steps 1000, 1010, 1030 and 1040 illustrated in FIG. 5, a layer 101 of plating material (copper, for instance) is deposited on a surface of the carrier 100.

Subsequently to unloading 1040 the articles 12, the carrier is exposed to a stripping bath 1060 that may be selectively activated (stripper current ON/OFF) to partially remove plating material from the layer 101 plated on the surface of the carrier 100.

The thickness of the residual layer 101′ may be measured 1070 (via one or more optical sensors S) and the measured value may be used to configure (ON/OFF) the stripping bath 1060 of the following processing cycle.

The carrier is thus loaded 1000 with another batch of articles 12 in order to facilitate processing of the articles 12.

FIG. 6 is a diagram illustrative of the thickness T (on the y axis) of the layer 101 (101′) prior (subsequently) to exposure of the carrier 100 to a stripping bath 1060 as a function of the number of processing cycles (on the x axis) the carrier 100 has gone through.

The references used in FIG. 6 are similar to those used in FIG. 4, that is: T_{1,i} indicates the thicknesses of the layer 101 of plating material prior to the i^{th} stripping bath, and T_{2,i} indicates the thicknesses of the (residual) layer 101′ of plating material subsequently to the i^{th} stripping bath 1060.

An upper T′ₕ and a lower T′ₗ threshold value may be used for determining whether the stripper current in the stripper bath 1060 of the subsequent processing cycle is turned ON/OFF. The accent is used for the thresholds T′ₕ and T′ₗ to highlight the fact that the threshold values used for the embodiments illustrated in FIGS. 5 and 6 may be different from the values (Tₕ and Tₗ, with no accent) used in the embodiments discussed in relation to FIGS. 3 and 4.

The stripper current may be assumed to be turned OFF in the first cycle and, consequently, T_{2,1}=T_{1,1}. Plating material will start accumulating on the surface of the carrier 100 in response to repeated (at each processing cycle) exposure of the carrier to a plating bath 1010.

Eventually, the thickness of the residual layer 101′ (measured 1070 after every stripping bath 1060) will be greater than the upper threshold value T′ₕ. In the exemplary case illustrated in FIG. 6, the measured thickness of the residual layer 101′ at the fourth processing cycle T_{2,4} is found to be greater than the upper threshold T′ₕ. Consequently, the stripper current of the stripping bath 1060 of the following (the fifth working cycle) processing cycle is turned ON and a selected partial amount of plating material is removed from the surface of the carrier 100.

Desirably, the amount of plating material removed in the stripping bath 1060 (with the stripper current turned ON) is larger than the amount of material that accumulates during a plating step 1010 (this fact is illustrated in FIG. 6, wherein T_{2,5}<T_{2,4}).

The stripper current of the stripping bath 1060 is kept ON for the following working cycles as long as the thickness of the residual layer 101′ (measured 1070 after exposure to the stripping bath 1060) is greater than the lower threshold T′₁. When the measured 1070 thickness of the residual layer 101′ is less than the low threshold T′₁ (at eight processing cycle in the example) the stripper current is turned OFF for the following working cycles.

Also in this case, the residual layer 101′ thickness oscillates with the processing cycles staying-possibly with the exceptions of the first processing cycles-within the range of values referenced with the reference R in the figure; for a given amount of plating material that is deposited on the carrier 100 after each plating step 1010, the residual layer 101′ thickness may be maintained within a desired range R (5 to 10 microns, for instance) by adjusting the threshold values T′ₕ, T′ₗ and/or the amount of plating material that is removed in the stripping bath 1060 (when the stripper current is ON).

Embodiments as described in relation to FIGS. 3 and 4 and FIGS. 5 and 6 may advantageously be applied, for example, in manufacturing processes where a relatively small amount of plating material accumulates on the surface of the carrier 100 at every processing cycle, in response to exposure to a plating bath 1010.

Said in other words, embodiments described in relation to FIGS. 3 to 6 may involve selectively stripping the layer 101 of plating material plated on the surface of the carrier in an activatable stripping bath and selectively activating the stripping bath.

The stripping bath may be selectively activated as a function of a thickness of the layer 101 of plating material plated on the surface of the carrier 100 in response to the plating step, as described in relation to FIGS. 3 and 4.

Alternatively, the stripping bath may be selectively activated as a function of a thickness T2 of residual protective layer 101′ on the surface of the carrier 100 in response to the selectively stripping of the plating material 101 plated on said surface of the carrier 100, that is, left on the surface of the carrier in a preceding working cycle.

FIGS. 7A to 7D are illustrative of a process of manufacturing of articles 12 involving two (or more) plating steps where two (or more) layers of plating material are sequentially grown/deposited on the surface of the carrier 100; this may be the case, for instance, of NEAP processing described in the foregoing.

FIG. 7A is a cross-sectional view of the surface of the carrier 100, similarly to what is illustrated in FIG. 2A.

The carrier 100 (with the articles 12 candidate for processing attached thereto) is dipped in a sequence of processing baths causing a plurality of layers to grow/deposit on the surface of the carrier 100. FIG. 7B is illustrative of two layers 101, 102 of metallic material, for instance, grown on the surface of the carrier 100.

In the case of a carrier 100 for treating leadframes 12 (NEAP processing, for instance) the first layer 101 may comprise copper plating material and the second layer 102 may comprise silver plating material.

In order to counter undesired accumulation of material on the surface of the carrier 100, the carrier 100 having plated on a surface thereof two (or more) layers 101, 102 is processed in a sequence of stripping baths (possibly after detaching the articles 12 from the carrier 100).

In the case illustrated in FIGS. 7A to 7D the carrier 100 is processed in two stripping baths.

As illustrated in FIG. 7C, a first stripping bath removes (completely) the second layer 102 thus exposing the first layer 101 (having a thickness T1) plated on the surface of the carrier 100.

The carrier 100 is thus processed in a second stripping bath. Similar to what has been discussed in the foregoing, the plating material of the first layer 101 is selectively stripped to partially remove material from the first layer 101 thus leaving, as illustrated in FIG. 7D, a residual protective layer 101′ possibly having a thickness T2 less than the thickness T1 (T2<T1).

The amount of material that is removed from the layer 101 via a stripping bath may be determined based on the measured thickness T1 of the layer 101 (measured via optical sensor S, for instance) and on the thickness of the residual layer 101′ that is desired to leave on the surface of the carrier 100.

The sequence of steps illustrated in FIGS. 7A to 7D refers for simplicity to the case where two layers 101, 102 (possibly two different plating materials) are grown/deposited on the surface of the carrier 100 in response to the carrier being dipped in corresponding processing baths. However, the person skilled in the art may appreciate that solutions as described herein may be applied also to the case where more than two layers are grown on the surface of the carrier; similarly to what has been described in relation to FIGS. 7A to 7D, further layers (such as the layer 102) grown on the first layer 101 deposited on the surface of the carrier 100 may be sequentially removed via respective stripping baths. Subsequently to removing the further layers 102, the first layer 101 grown on the surface of the carrier 100 may be selectively and partially removed to leave a protective layer 101′ having a desired thickness (5 to 10 microns, for instance).

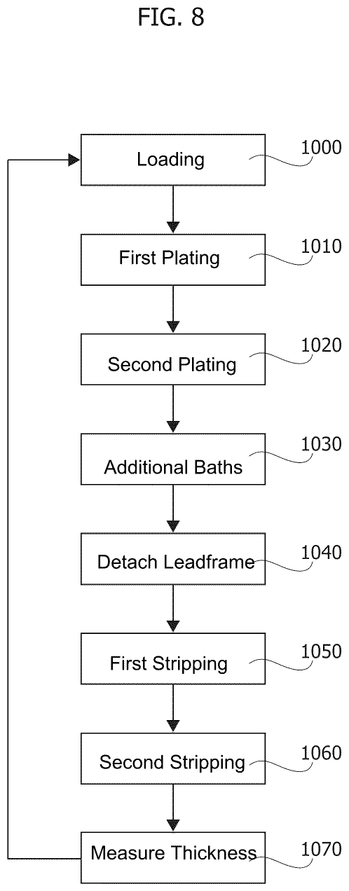

FIG. 8 is a flow chart illustrative of embodiments of the present description where a same carrier 100 is used in a plurality of processing cycles involving two (or more) plating steps.

The processing steps illustrated in FIG. 8 comprise: loading 1000 the articles 12 candidate for processing on the carrier 100; a first plating step 1010, where a first plating material (copper, for instance) deposits on the carrier 100 forming a first layer 101; a second plating step 1020, where a second layer 102 of a second, possibly different, plating material (silver or tin, for instance) deposits on the layer 101 of first plating material formed on the surface of the carrier 100; further processing 1030, such as additional processing bath that do not result in further material being deposited on the carrier 100, for instance; and unloading 1040 of (processed) articles 12 from the carrier 100.

The carrier 100 is processed in a first stripping bath 1050 configured to remove the second layer 102 of second material, thus exposing the first (base) layer 101. As mentioned, the second layer 102 may be a silver layer 102; in that case, the carrier 100 is processed (dipped) in a corresponding silver stripping bath 1050.

After the first stripping bath 1050 the carrier is processed in a second stripping bath 1060 that is configured to leave a protective residual layer 101′ on the surface of the carrier.

In the embodiment illustrated in FIG. 8, optical sensor(s) S may be used to measure 1080 the thickness of the residual protective layer 101′ after the stripping bath 1060. The measured thickness may be used to configure the stripping bath 1060 of the subsequent processing cycle (turning ON/OFF the stripper current, for instance) similarly to what has been described in the foregoing in relation to FIGS. 5 and 6; in order not to make the description unduly long, a detailed description will not be repeated herein.

In summary, according to embodiments described in relation to FIGS. 7A to 7D and FIG. 8, the sequence of processing steps may include: a first plating step wherein a (first) base layer 101 of plating material is plated on a surface of the carrier 100; and at least one further plating step wherein further plating material (the layer 102, for instance) is plated onto the base layer 101 of plating material plated on the surface of the carrier 100.

The further plating material plated onto the base layer 101 is removed from the base layer 101 and, subsequently, the base layer 101 of plating material is selectively stripped to partially remove plating material therefrom, thus leaving a residual protective layer 101′ of plating material on the surface of the carrier 100.

FIG. 9 is illustrative of an apparatus A for processing articles 12 (such as leadframes, for instance) as described in the foregoing.

As schematically illustrated, articles 12 are carried by a carrier 100 through a sequence of workstations comprising on or more plating workstations (P1, P2, . . . , PN) and one or more stripping workstations (SN, . . . , S2, S1). Processing workstations other than plating and/or stripping workstation may be included in the apparatus A; these further workstations are not visible in FIG. 9 for simplicity.

The plating workstation P1 is configured to process the articles 12 carried by the carrier 100 in a plating bath, wherein a base layer 101 of plating material is plated on a surface of the carrier 100.

The stripping workstation S1 is configured to selectively strip the plating material 101 plated on said surface of the carrier 100 to partially remove the base layer 101 of plating material plated on the surface of the carrier 100 leaving a residual protective layer 101′ of plating material on the surface of the carrier 100

As illustrated the apparatus A may also comprise: further plating workstations P2, . . . , PN configured to process the articles 12 carried by the carrier 100 in further plating baths that result in further plating material (sequentially) plated onto the base layer, and further stripping workstations SN, . . . , S2 configured to strip the further plating material plated onto the base layer that result in the further plating material being removed from the base layer 101.

Without prejudice to the underlying principles, the details and the embodiments may vary, even significantly, with respect to what has been described by way of example only without departing from the scope of the embodiments.

The claims are an integral part of the technical teaching provided herein in respect of the embodiments.

The extent of protection is determined by the annexed claims.

1. A method, comprising:
processing articles carried by a carrier in a sequence of processing steps including at least one plating step wherein a base layer of plating material is plated on a surface of the carrier, and
selectively stripping the plating material plated on said surface of the carrier to partially remove the plating layer and reduce a thickness of the base layer of plating material plated on the surface of the carrier leaving a residual protective layer of plating material on the surface of the carrier.

2. The method of claim 1, wherein the residual protective layer left of the surface of the carrier has a thickness in the range between 5 and 10 microns.

3. The method of claim 1, wherein the carrier comprises a reel-to-reel belt and further comprising: attaching leadframes to the reel-to-reel belt; processing the leadframes attached to the reel-to-reel belt through said sequence of processing steps; and detaching the leadframes from the reel-to-reel belt before performing the step of selectively stripping.

4. The method of claim 1, wherein said at least one plating step comprises a copper plating step wherein a base layer of copper plating material is plated on said surface of the carrier, and selectively stripping comprises selectively stripping the copper plating material of the base layer plated on said surface of the carrier leaving a residual protective layer of copper plating material on the surface of the carrier.

5. The method of claim 1:
wherein the sequence of processing steps includes:
a first plating step wherein said base layer of plating material is plated on said surface of the carrier; and
at least one further plating step wherein further plating material is plated onto the base layer of plating material plated on the surface of the carrier;
wherein selectively stripping comprises:
stripping to completely remove the further plating material plated onto the base layer of plating material plated on the surface of the carrier; and
then selectively stripping the base layer of plating material to partially remove the base layer of plating material plated on the surface of the carrier leaving a residual protective layer of plating material of reduced thickness on the surface of the carrier.

6. The method of claim 5, wherein the further plating material comprises silver plating material, and wherein selectively stripping comprises stripping the silver plating material.

7. The method of claim 1, wherein selectively stripping the base layer of plating material comprises:
exposing the base layer of plating material to a stripping bath; and
selectively activating said stripping bath to selectively strip the base layer of plating material.

8. The method of claim 7, wherein selectively activating said stripping bath is performed as a function of a thickness of the base layer of plating material.

9. The method of claim 8, wherein said thickness of the base layer of plating material comprises a thickness of the layer of plating material plated on the surface of the carrier in response to said at least one plating step.

10. The method of claim 9, further comprising measuring via optical sensing the thickness of the layer of plating material plated on the surface of the carrier in response to said at least one plating step.

11. The method of claim 8, wherein said thickness of the base layer of plating material comprises a thickness of the residual protective layer on the surface of the carrier in response to said selectively stripping the plating material plated on said surface of the carrier.

12. The method of claim 11, further comprising measuring via optical sensing the thickness of the layer of plating material plated on the surface of the carrier in response to the thickness of residual protective layer on the surface of the carrier.

13. An apparatus for processing articles carried by a carrier according to claim 1, wherein the apparatus comprises:
a plating workstation configured to process the articles carried by the carrier in a plating bath, wherein a base layer of plating material is plated on a surface of the carrier; and
a stripping workstation configured to selectively strip the plating material plated on said surface of the carrier to partially remove the base layer of plating material plated on the surface of the carrier leaving a residual protective layer of plating material on the surface of the carrier.

14. The apparatus of claim 13, comprising:
at least one further plating workstation configured to process the articles carried by the carrier in further plating baths, wherein further plating material is plated onto the base layer of plating material plated on the surface of the carrier, and
at least one further stripping workstation configured to strip the further plating material plated onto the base layer of plating material plated on the surface of the carrier, wherein the further plating material is removed from said base layer of plating material plated on the surface of the carrier in response to stripping the further plating material.
